(19) United States
(12) Patent Application Publication
(10) Pub. No.: US 2025/0325998 A1
(43) Pub. Date: Oct. 23, 2025

(54) SPRAYING DEVICE, SPRAYING SYSTEM AND OPERATING METHOD THEREOF FOR SEMICONDUCTOR SUBSTRATE

(71) Applicant: GRAND PROCESS TECHNOLOGY CORPORATION, Hsinchu City (TW)

(72) Inventors: Chia-kang WANG, Hsinchu City (TW); Chun-hao LIN, Hsinchu City (TW)

(21) Appl. No.: 18/675,472

(22) Filed: May 28, 2024

(30) Foreign Application Priority Data
Apr. 19, 2024 (TW) 113114696

(51) Int. Cl. B05B 12/14; H01L 21/67

(52) U.S. Cl. CPC B05B 12/1418; H01L 21/67051; H01L 21/67075

(57) ABSTRACT

A spraying device, a spraying system, and an operating method thereof for a semiconductor substrate are provided. The spraying device includes a main channel and at least one branch channel. The main channel has a main channel inlet and a main channel outlet provided for gas to flow from the main channel inlet to the main channel outlet. The at least one branch channel is communicated with the main channel, and each of the at least one branch channel has a branch channel inlet provided for fluid to flow from the branch channel inlet to the main channel outlet.

### CROSS REFERENCE TO RELATED APPLICATIONS

The present invention claims priority of the Taiwan Patent Application No. 113114696, filed on Apr. 19, 2024 with the Taiwan Intellectual Property Office, titled “Spraying device, spraying system and operating method thereof for semiconductor substrates”, which is incorporated by reference in the present invention in its entirety.

### FIELD OF INVENTION

The present disclosure relates to a spraying device and a spraying system and an operating method thereof, and more particularly, to a spraying device and a spraying system for a semiconductor substrate and an operating method thereof.

### BACKGROUND OF INVENTION

In the prior art, when etching or cleaning a surface of a semiconductor substrate (such as a wafer, etc.), due to liquid remaining in nozzles and pipelines communicated with the nozzles, the liquid often remains after a predetermined etching time is exceeded. The residual liquid drips from the nozzles onto the semiconductor substrates cause a decrease in yield of the cleaning and etching process.

Generally speaking, after spraying etching liquid, deionized water or other solvents are sprayed immediately to remove the etching liquid on the surfaces of the semiconductor substrates to prevent the semiconductor substrates from being etched by too much of the etching liquid. However, since deionized water cannot be stored in the same container as the etching liquid (e.g., etching solution), nor can it be sprayed using the same pipeline. In practice, even if a process is set to spray deionized water immediately after etching, waiting time for the nozzle of the etching solution to remove and the nozzle of the deionized water to move to a specific position is still required. A portion of the etching solution still remains on the semiconductor substrate during this time, causing excessive etching of the semiconductor substrate or damage to the surface structure.

Furthermore, since deionized water and the etching solution are not sprayed from the same nozzle, or even on the same moving mechanism, when moving and replacing different nozzles, time differences and positioning deviations are prone to occur, resulting in a decrease in the overall controllability of the semiconductor manufacturing process. Furthermore, it requires a substantially amount of time and labor consumption for parameters adjustment and optimizing. In addition, the pipelines and the nozzles that have been immersed in high-concentration etching solutions for a long time are easily corroded or clogged by crystals formed by the chemical in the etching solution, further increasing problems of reduced process yield, increased consumables, and increased costs.

Therefore, a spraying device and a spraying system with a single fluid outlet, and an operating thereof are urgently needed in the technical field of the present invention, which can prevent the solution from dripping on the semiconductor substrate, prevent the solution from clogging and crystallizing in the pipeline, and can mix the chemical in the etching liquid in the pipeline.

### SUMMARY OF INVENTION

The spraying device and spraying system and an operating method thereof for a semiconductor substrate provided by the present invention can complete cleaning of channels of the spraying device and cleaning of surface of the semiconductor substrate while the process is in progress through the arrangement design of a main channel and at least one branch channel, so as to prevent chemical in the etching liquid from forming crystals and causing corrosion of the channels or nozzles and require replacement.

In view of the above problems, in order to solve conventional problems such as excessive etching caused by chemical solution droplets on the surface of a semiconductor substrate, the present invention provides a spraying device for spraying at least one semiconductor substrate, the spraying device includes: a main channel including a main channel inlet and a main channel outlet for gas to flow from the main channel inlet to the main channel outlet; and at least one branch channel is communicated with the main channel, and each of the at least one branch channel has a branch channel inlet provided for fluid to flow from the branch channel inlet to the main channel outlet.

In a preferred embodiment, the at least one branch channel further includes: a first branch channel, having a first branch channel inlet; and a second branch channel, having a second branch channel inlet. The first branch channel is more adjacent to the main channel inlet of the main channel than the second branch channel, so that a first fluid flows into the first branch channel from the first branch channel inlet, then enters the main channel, and then after passing through the second branch channel, the first fluid flows to the main channel outlet.

In a preferred embodiment, the at least one branch channel further includes: a third branch channel, having a third branch channel inlet. The third branch channel is further away from the main channel inlet of the main channel than the first branch channel and the second branch channel, so that the first fluid flows into the first branch channel from the first branch channel inlet, then enters the main channel, and then after passing through the second branch channel and the third branch channel in sequence, the first fluid flows to the main channel outlet.

In a preferred embodiment, the second branch channel inlet is provided for a second fluid to flow from the second branch channel into the main channel, the third branch channel inlet is provided for a third fluid to flows from the third branch channel into the main channel, and the second fluid and the third fluid enter the main channel to be mixed and then flow to the main channel outlet.

In a preferred embodiment, the at least one branch channel further includes: a first branch channel, having a first branch channel inlet; and a second branch channel, having a second branch channel inlet. A distance between a position where the first branch channel is communicated with the main channel and the main channel inlet of the main channel, and a position where the second branch channel is communicated with the main channel and the main channel inlet of the main channel in a vertical direction are the same.

In a preferred embodiment, the main channel inlet and each of the branch channel inlet respectively have a valve to control opening or closing of the main channel and each of the at least one branch channel.

The present invention also provides a spraying system, which includes: at least one semiconductor substrate; the spraying device according any one of the above-mentioned embodiments disposed above the at least one semiconductor substrate, wherein the main channel inlet and the branch channel inlet of the spraying device each have a valve for controlling opening or closing of the main channel and the at least one branch channel; a plurality of flow controllers, respectively communicated with the valve of the main channel and the valve of each of the at least one branch channel, configured to monitor a flow rate of the gas or the fluid; and a control module, signally connected to the spraying device and the plurality of flow controllers, configured to adjust flow of the gas or the fluid, and the opening or closing of the main channel and each of the at least one branch channel.

In a preferred embodiment, the at least one branch channel further includes a first branch channel and a second branch channel, and the main channel, the first branch channel, and the second branch channel respectively have a main valve, a first valve, and a second valve. The first branch channel has a first branch channel inlet provided for a first fluid to flow from the first branch channel inlet to the main channel outlet, and the second branch channel has a second branch channel inlet provided for a second fluid to flow from the second branch channel inlet to the main channel outlet. The first branch channel is more adjacent to the main channel inlet of the main channel than the second branch channel, so that the first fluid flows into the first branch channel from the first branch channel inlet, then enters the main channel, and then after passing through the second branch channel, the first fluid flows to the main channel outlet. The main valve, the first valve, and the second valve are respectively provided to control opening or closing of the main channel, the first branch channel, and the second branch channel, and are respectively communicated with one of the plurality of flow controllers.

In a preferred embodiment, the at least one branch channel further includes: a third branch channel having a third branch channel inlet provided for a third fluid to flow from the third branch channel inlet to the main channel outlet. The first branch channel is more adjacent to the main channel inlet of the main channel than the second branch channel and the third branch channel, and the second branch channel is more adjacent to the main channel inlet than the third branch channel, so that the first fluid flows into the first branch channel from the first branch channel inlet, then enters the main channel, then after passing through the second branch channel and the third branch channel in sequence, the first fluid flows to the main channel outlet, and so that the second fluid flows into the second branch channel from the second branch channel inlet, then enters the main channel, and after passing through the third branch channel, the second fluid flows to the main channel outlet.

The present invention further provides an operating method of the spraying system according to any one of the above-mentioned embodiments for a semiconductor substrate. The operating method includes: opening the second valve, and spraying the second fluid on the at least one semiconductor substrate.

In a preferred embodiment, the operating method further includes: when detecting that an opening time of the second valve has reached a preset time value, closing the second valve, and opening the first valve.

In a preferred embodiment, the operating method further includes: opening the first valve, and spraying the first fluid on the at least one semiconductor substrate.

In a preferred embodiment, the operating method further includes: when detecting that an opening time of the first valve has reached a preset time value, closing the first valve, and opening the main valve.

In a preferred embodiment, the operating method further includes: opening the main valve, and spraying the gas on the at least one semiconductor substrate.

In a preferred embodiment, the operating method further includes: when detecting that an opening time of the main valve has reached a preset time value, closing the main valve.

In a preferred embodiment, the operating method further includes: opening the second valve and the third valve, mixing the second fluid and the third fluid in the main channel, and spraying the second fluid and the third fluid on the at least one semiconductor substrate.

In a preferred embodiment, the operating method further includes: when detecting that an opening time of the second valve and an opening time of the third valve has reached a preset time value, closing the second valve and the third valve, and opening the first valve.

Compared with the prior art, the spraying device, the spraying system and the operating method thereof for a semiconductor substrate provided by the present invention can reduce a risk of fluid still being in the channels causing a problem of dripping chemicals in the channels on a surface of the semiconductor substrate, when the valve opening time reaching the required preset time value during a semiconductor manufacturing process. Therefore, a yield or a productivity of an overall process (such as a cleaning efficiency after wafer etching) are enhanced, while reducing replacements of expensive consumables and reducing process costs.

### BRIEF DESCRIPTION OF DRAWINGS

The following describes specific embodiments of the present invention in detail with reference to the accompanying drawings, which will make technical solutions and other beneficial effects of the present invention obvious.

FIG. 1 is a schematic perspective view of a spraying device for a semiconductor substrate according to an embodiment of the present invention.

FIG. 2 is a schematic perspective view of the spraying device for a semiconductor substrate according to another embodiment of the present invention.

FIG. 3 is a schematic perspective view of the spraying device for a semiconductor substrate according to yet another embodiment of the present invention.

FIG. 4 is a schematic view of a spraying system for a semiconductor substrate according to an embodiment of the present invention.

FIG. 5 is a schematic perspective view of the spraying system for a semiconductor substrate according to an embodiment of the present invention.

FIG. 6 is a schematic flowchart of an operating method of the spraying system for a semiconductor substrate according to an embodiment of the present invention.

FIG. 7 is a schematic flowchart of an operating method of the spraying system for a semiconductor substrate according to another embodiment of the present invention.

### DETAILED DESCRIPTION OF PREFERRED EMBODIMENTS

Before describing at least one embodiment of the present disclosure in detail, it should be understood that the present disclosure is not necessarily limited to its application in the details illustrated in the following examples, for example, the number of embodiments, specific mixing ratio used thereof, etc. The present disclosure can be implemented or realized in other embodiments or in various ways.

The following will describe embodiments according to the present invention with reference to relevant drawings. For ease of understanding, the same components in the following embodiments are labeled with the same symbols.

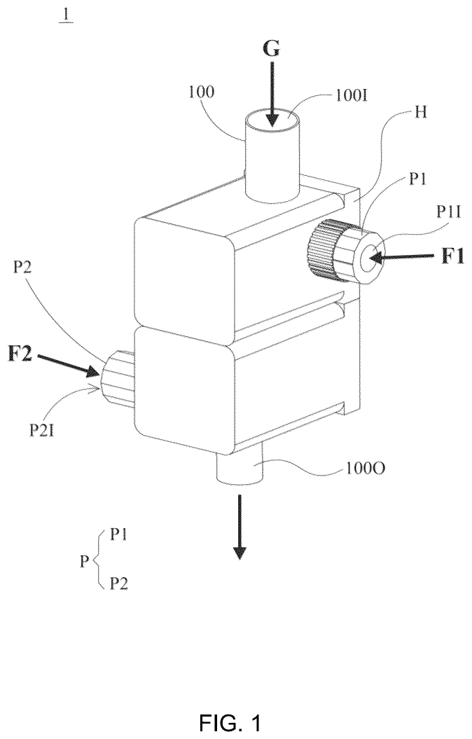

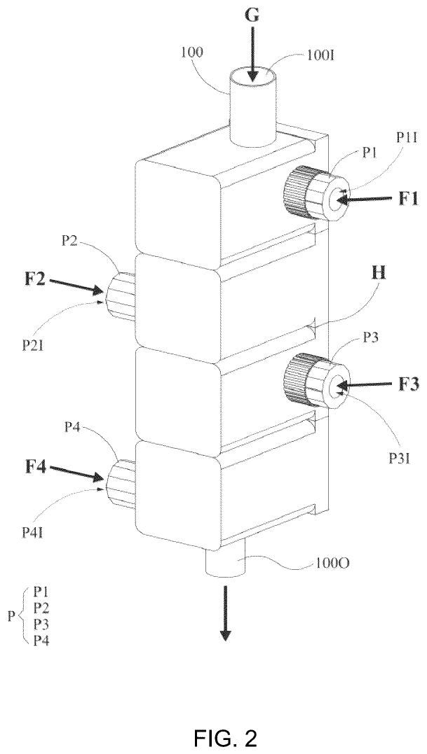

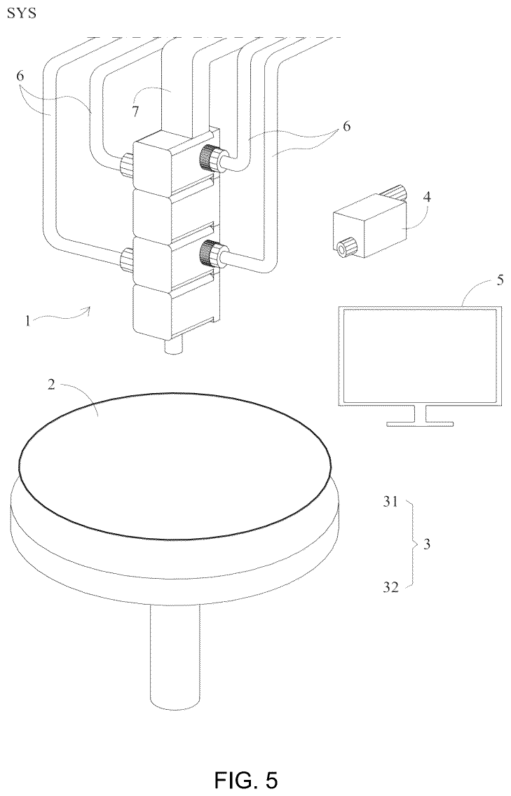

Referring to FIGS. 1 and 2, FIG. 1 is a schematic perspective view of a spraying device for a semiconductor substrate according to an embodiment of the present invention, and FIG. 2 is a schematic perspective view of the spraying device for a semiconductor substrate according to another embodiment of the present invention. The present invention provides a spraying device 1 for spraying at least one semiconductor substrate 2 (see FIG. 5, detailed below). in addition, “spraying” of the present invention can include cleaning, spraying, or vaporizing, the present invention is not limited to the foregoing examples or implementations, and can be adjusted according to actual process requirements.

As shown in FIGS. 1 and 2, the spraying device 1 includes: a main channel 100 and at least one branch channel P. The main channel 100 has a main channel inlet 100I and a main channel outlet 100O, provided for gas G to flow from the main channel inlet 100I to the main channel outlet 100O. At least one branch channel P is communicated with the main channel 100, and each of the at least one branch channel P has a channel inlet P1I, P2I, P3I, P4I provided for fluids F1, F2, F3, F4 from the branch channel inlet P1I, P2I, P3I, P4I to flow to the main channel outlet 100O. The main channel outlet 100O is configured to spray the gas G or the fluids F1, F2, F3, F4 on the at least one semiconductor substrate 2. Furthermore, the main channel 100 and the at least one branch channel P are covered by a shell H on outside thereof to protect connections between the channels and to prevent the channels from damaging due to collision.

Reference is further made to FIG. 1. In the spraying device 1 of the present invention, the at least one branch channel P further includes: a first branch channel P1 and a second branch channel P2. The first branch channel P1 has a first branch channel inlet P1I, and the second branch channel P2 has a second branch channel inlet P2I.

In one embodiment, the first branch channel inlet P1I of the first branch channel P1 is communicated with a deionized water supply source (not shown) provided for deionized water to flow from the first branch channel inlet P1I to the main channel outlet is 100O. The second branch channel inlet P2I of the second branch channel P2 is communicated with a chemical solution supply source (not shown) provided for the chemical solution to flow from the second branch channel inlet P2I to the main channel outlet. The main channel inlet 100I of the main channel 100 is communicated with a gas supply source (not shown) provided for the gas G to flow from the main channel inlet 100I to the main channel outlet 100O. Specifically, in an embodiment of the present invention, the deionized water can be reverse osmosis (RO) water, pure water, or other water that removes salts or anions and cations from water (deionized water, DI water); the chemical solution can be sulfuric acid, hydrochloric acid, nitric acid, hydrogen peroxide or other solvents; in addition, the gas G can be nitrogen or other noble gases, and the present invention is not limited to types of the chemical solution, the deionized water, or the gas G.

As shown in FIG. 1, in one embodiment, the first branch channel P1 is more adjacent to the main channel inlet 100I of the main channel 100 than the second branch channel P2, so that a first fluid F1 (for example, deionized water) flows into the first branch channel P1 from the first branch channel inlet P1I, then enters the main channel 100, and then after passing through the second branch channel P2, the first fluid F1 flows to the main channel outlet 100O. A second fluid F2 (for example, a chemical solution) flows into the second branch channel P2 from the second branch channel inlet P2I, then enters the main channel 100, and then flows to the main channel outlet 100O. That is to say, the first branch channel P1 is higher than the second branch channel P2 in the vertical direction, and the first branch channel P1 is located “upstream” of the second branch channel P2 in the main channel 100. That is, the first branch channel P1 and the second branch channel P2 are communicated with the main channel 100 in a “series” manner.

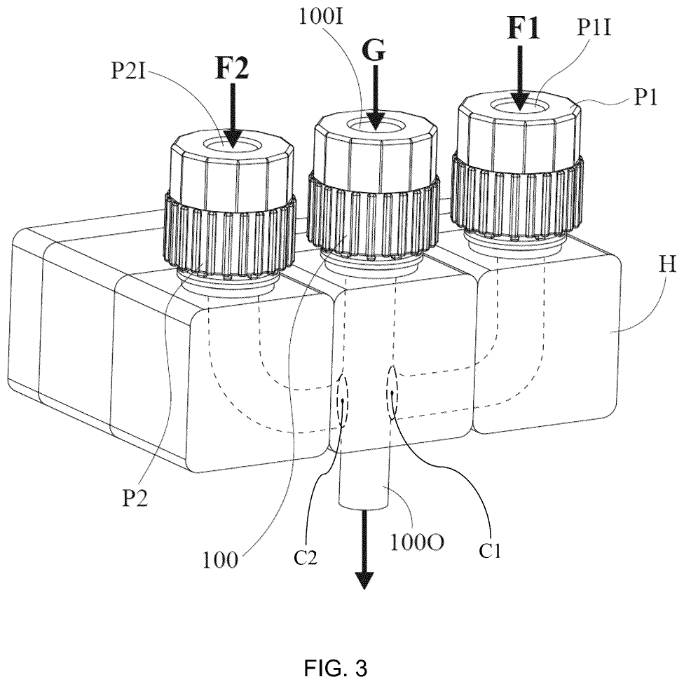

Referring to FIG. 3, and in conjunction with FIG. 1, FIG. 3 is a schematic perspective view of a spraying device for a semiconductor substrate provided by yet another embodiment of the present invention. As shown in FIG. 3, in one embodiment, a distance between a position where the first branch channel P1 is communicated with the main channel 100 and the main channel inlet 100I of the main channel 100, and a distance between a position where the second branch channel P2 is communicated with the main channel 100 and the main channel inlet 100I of the main channel 100 in the vertical direction is the same, so that the first fluid F1 flows into the first branch channel P1 from the first branch channel inlet P1I, then enters the main channel 100, and then flow to the main channel outlet 100O. Specifically, the first branch channel P1 is communicated with the main channel 100 at a first connection point C1, the second branch channel P2 is communicated with the main channel 100 at a second connection point C2, and the first connection point C1 and the second connection point C2 are located on a same horizontal plane. That is to say, a vertical height of the first connection point C1 and a vertical height the second connection point C2 are the same, and the first branch channel P1 and the second branch channel P2 are communicated with the main channel 100 in a “parallel” manner, and has no such differences as being upstream or downstream. As shown in FIG. 3, it should be noted that the first connection point C1 and the second connection point C2 are respectively virtual points. For example, a cross section of where the first branch channel P1 is communicated with the main channel 100 and a cross section of where the second branch channel P2 is communicated with the main channel 100 can be a circle, and the first connection point C1 and the second connection point C2 can be located at a center of the circle, respectively, but the invention is not limited thereto. In addition, the connection manner shown in FIG. 3 is only an example. The first branch channel P1 and the second branch channel P2 are communicated with the main channel 100 at an angle of 90 degrees. In other embodiments, the first branch channel P1 and the second branch channel P2 can also be communicated with the main channel 100 at an angle of 45 degrees, or at other angles, and the invention is not limited thereto.

That is to say, no matter whether the first branch channel P1 and the second branch channel P2 are communicated with the main channel 100 in series or in parallel, the first fluid F1 flows through everywhere that the second fluid F2 flows through in the main channel 100. When the first fluid F1 is deionized water, after the second fluid F2 flows through both the main channel 100 and the main channel outlet 100O, the main channel 100 and the main channel outlet 100O are cleaned by the first fluid F1, so that preventing the channels in the spraying device 1 of the present invention from being clogged by crystals, or corroded due to long-term use of the chemical solution.

As shown in FIG. 2, in one embodiment, the at least one branch channel P further includes: a third branch channel P3. The third branch channel P3 has a third branch channel inlet P3I. The first branch channel P1 is more adjacent to the main channel inlet 100I of the main channel 100 than the second branch channel P2 and the third branch channel P3. The second branch channel P2 is more adjacent to the main channel inlet 100I of the main channel 100 than the third branch channel P3, so that the first fluid F1 flows into the first branch channel P1 from the first branch channel inlet P1I, then enter the main channel 100, and then after passing through the second branch channel P2 and the third branch channel P3 in sequence, the first fluid F1 flows to the main channel outlet 100O, and so that the second fluid F2 flows from the second branch channel inlet P2I into the second branch channel P2 and then enters the main channel 100, and then after passing through the third branch channel P3, the second fluid F2 flows to the main channel outlet 100O. In other embodiments, the at least one branch channel P can further include a fourth branch channel P4, and the fourth branch channel P4 has a fourth branch channel inlet P4I.

That is to say, a number of the at least one branch channel P can be plural, and as shown in FIGS. 1 to 3, the first branch channel P1 to the fourth branch channel P4 can be connected in series along the main channel 100, and more branch channels can also be added according to actual requirements. The remaining implementation of multiple branch channels have been described in the foregoing embodiments, and will not be reiterated herein. It should be noted that for the chemical solution and deionized water flowing into the first branch channel P1, the second branch channel P2, a third branch channel P3, and a fourth branch channel P4 can be the same or different from each other, and can be adjusted according to actual requirements, the present invention is not limited thereto. In other embodiments, types of fluid can also be adjusted according to the number of channels.

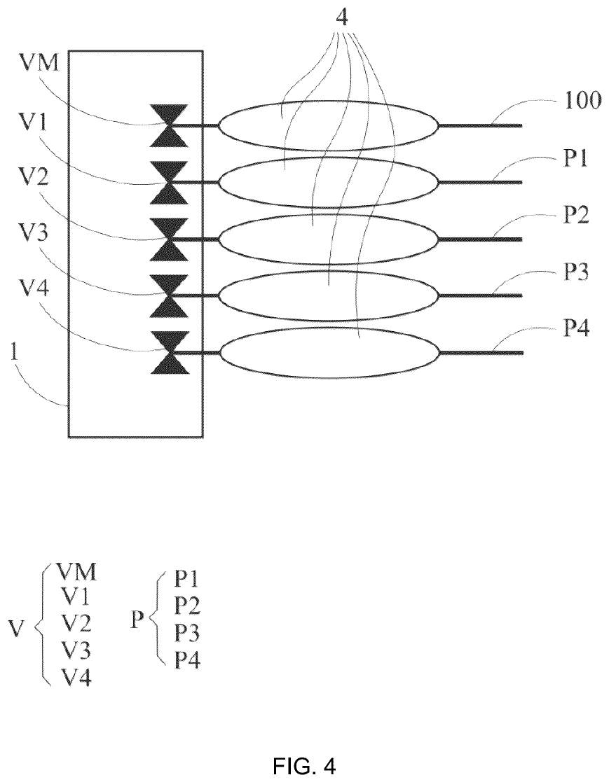

Referring to FIGS. 1 to 3, and referring to FIG. 4, which is a schematic view of a spraying system for a semiconductor substrate according to an embodiment of the present invention. In one embodiment, the main channel 100 and each of the branch channels P1, P2, P3, P4 respectively have a valve VM, V1, V2, V3, V4 for controlling opening and closing of the main channel 100 and each of the at least one branch channel P. Specifically, the main channel 100 has a main valve VM, the first branch channel P1 has a first valve V1, the second branch channel P2 has a second valve V2, the third branch channel P3 has a third valve V3, and the fourth branch channel P4 has a fourth valve V4. It is worth mentioning that, for the sake of simplicity, the valves VM, V1, V2, V3, and V4 of the present invention are omitted in some drawings. In addition, the valves VM, V1, V2, V3, V4 can be provided at any position that can control the main channel 100 and the branch channels P1, P2, P3, P4, and can be, for example, pneumatic valves or solenoid valves, but the present invention is not limited thereto. In one embodiment, each of the branch channels P can be assembled in a modular manner. As long as connections between each of the branch channels P and the main channel 100 after being assembled is ensured, they can be connected in series, parallel, or a combination thereof, the present invention does not limit an actual arrangement of the assembly. In this way, the application flexibility of the spraying device 1 of the present invention in different processes can be increased.

Referring to FIG. 5, which is a schematic perspective view of a spraying system for a semiconductor substrate according to an embodiment of the present invention. The present invention also provides a spraying system SYS, which includes: the at least one semiconductor substrate 2, the spraying device 1 as described in any of the above-mentioned embodiments, a plurality of flow controllers 4, and a control module 5. The spraying device 1 is disposed above the at least one semiconductor substrate 2. The plurality of flow controllers 4 are respectively communicated with the main channel 100 and the valves VM, V1, V2, V3, V4 of each of the at least one branch channel P, for monitoring the flow of the gas G or the fluids F1, F2, F3, F4. The control module 5 is signally connected to the spraying device 1 and the plurality of flow controllers 4 to adjust the flow of the gas G or the fluids F1, F2, F3, F4, the main channel 100, and at least one flow controller 4, and the opening or closing of the main channel 100 and the branch channel P. The control module 5 can be a programmable logic controller (PLC), an industrial personal computer (IPC) or other control device or equipment with computing and control functions; the plurality of flow controllers 4 can be a mass flow controller (MFC), and the present invention is not limited thereto.

In one embodiment, the spraying system SYS of the present invention further includes: a semiconductor substrate carrier 3, at least one branch channel supply pipeline 6, and a main channel supply pipeline 7. The number of the at least one branch channel supply pipeline 6 can be determined according to the number of the at least one branch channel P of the spraying device 1. The at least one branch channel supply pipeline 6 can be respectively communicated with, for example, a liquid storage tank or other storage device, and the at least one branch channel supply pipeline 6 can be communicated with, for example, a liquid nitrogen pressurized storage tank, a gas bottle, or other storage devices, and the present invention is not limited thereto. The semiconductor substrate carrier 3 is disposed below the at least one semiconductor substrate 2 for carrying the at least one semiconductor substrate 2. The semiconductor substrate carrier 3 includes a carrying rotating disk 31 and a carrying rotating shaft 32. The carrying rotating disk 31 can carry the at least one semiconductor substrate 2, and the carrying rotating shaft can be further connected to a driving device (not shown). Thereby, when the spraying device 1 in the spraying system SYS of the present invention is spraying, the semiconductor substrate carrier 3 can be driven and rotated by the driving device, and the at least one semiconductor substrate 2 disposed thereon can also be rotated. This allows the fluid and the gas sprayed on the at least one semiconductor substrate 2 to be detached at a specific speed, thereby reducing the risk of over-etching and yield reduction.

It is worth mentioning that the aforementioned plurality of flow controllers 4 are respectively connected to the valves VM, V1, V2, V3, V4 of the main channel 100 and each of the at least one branch channel P, and the control module 5 is signally connected to the spraying device 1 and the plurality of flow controllers 4, and the plurality of flow controllers 4 execute instructions issued by the control, but the present invention does not limit the specific implementation of the above-mentioned connection. In addition, the preset state of each of the valves VM, V1, V2, V3, V4 of the present invention is closed, which ensures that every opening and closing of each of the valves VM, V1, V2, V3, V4 is controlled by the control module 5.

Next, specific embodiments of the spraying system SYS of the present invention for spraying gas and fluid will be described below. At the same time, the present invention further provides an operating method for a semiconductor substrate of the spraying system SYS as described in any of the above-mentioned embodiments. The operating method can be implemented by using the spraying system SYS of the present invention and controlling the at least one branch channel P and the main channel 100 to spray gas and fluid. Regarding the spraying device 1 and the operating method of the spraying system SYS of the present invention, the specific implementation of the spraying device 1 has been described in previous embodiments, and therefore will not be reiterated herein.

### Embodiment of Spraying a Single Fluid and Spraying Gas After Spraying Deionized Water

In one embodiment, when the control module 5 controls the second valve V2 to open, the second fluid F2 flows from the second branch channel P2 into the main channel 100 and flows to the main channel outlet 100O before being sprayed on the at least one semiconductor substrate 2. When one of the plurality of flow controllers 4 of the second valve V2 detects that an opening time of the second valve V2 has reached a preset time value, the control module 5 controls the second valve V2 to close, and controls the first valve V1 to open. Then, the first fluid F1 flows from the first branch channel P1 into the main channel 100, then flows to the main channel outlet 100O, and then sprays on the at least one semiconductor substrate 2.

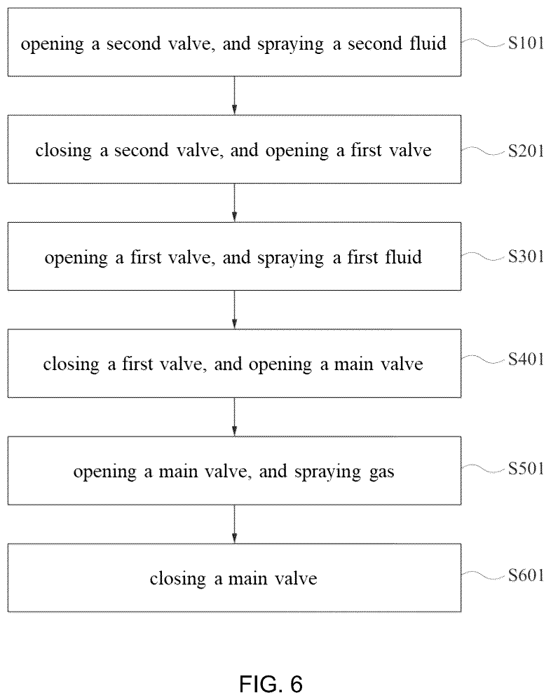

When one of the plurality of flow controllers 4 of the first valve V1 detects that an opening time of the first valve V1 has reached a preset time value, the control module 5 controls the first valve V1 to close, and control the main valve VM to open. Then, the gas G flows into the main channel 100 from the main channel inlet 100I, then flows to the main channel outlet 100O, and then sprays on the at least one semiconductor substrate 2. Then, when one of the plurality of flow controllers 4 of the main valve VM detects that an opening time of the main valve VM has reached a preset time value, the control module 5 controls the main valve VM to close. Referring to FIG. 6, which is a schematic flowchart of an operating method of a spraying device for a semiconductor substrate according to an embodiment of the present invention. Specifically, in this embodiment, the operating method of the spraying device 1 can include the following steps:
Step S101: opening the second valve V2, and spraying the second fluid F2;
Step S201: closing the second valve V2, and opening the first valve V1;
Step S301: opening the first valve V1, and spraying the first fluid F1;
Step S401: closing the first valve V1, and opening the main valve VM;
Step S501: opening the main valve VM, and spraying the gas G; and
Step S601: closing the main valve VM.

The steps of the aforementioned operating method can be performed through the spraying system SYS. Specifically, after spraying the chemical solution, deionized water and nitrogen can be sprayed sequentially to remove the chemical solution remaining in the main channel 100 and remaining on the at least one semiconductor substrate 2. Other details about the spraying system SYS and the spraying device 1 have been described in the previous embodiments, and will not be reiterated herein.

### Embodiment of Spraying Multiple Fluids and Spraying Gas After Spraying Deionized Water

In another embodiment, when the control module 5 controls the second valve V2 and the third valve V3 to open, the second fluid F2 flows from the second branch channel P2 into the main channel 100 and the third fluid F3 flows into the main channel 100 from the third branch channel P3. The second fluid F2 and the third fluid F3 are mixed in the main channel 100 and flow to the main channel outlet 100O, and then the second fluid F2 and the third fluid F3 spray on the at least one semiconductor substrate 2 at the same time. When two of the plurality of flow controllers 4 of the second valve V2 and the third valve V3 detect that the opening time of the second valve V2 and the third valve V3 has reached a preset time value, the control module 5 controls the second valve V2 and the third valve V3 to close, and controls the first valve V1 to open. Then, the first fluid F1 flows from the first branch channel P1 into the main channel 100, then flows to the main channel outlet 100O, and then sprays on the at least one semiconductor substrate 2.

As mentioned above, when one of the plurality of flow controllers 4 of the first valve V1 detects that the opening time of the first valve V1 has reached the preset time value, the control module 5 controls the first valve V to close and controls the main valve VM to open. Then, the gas G flows into the main channel 100 from the main channel inlet 100I, then flows to the main channel outlet 100O, and then sprays on the at least one semiconductor substrate 2. Then, when one of the plurality of flow controllers 4 of the main valve VM detects that the opening time of the main valve VM has reached the preset time value, the control module 5 controls the main valve VM to close.

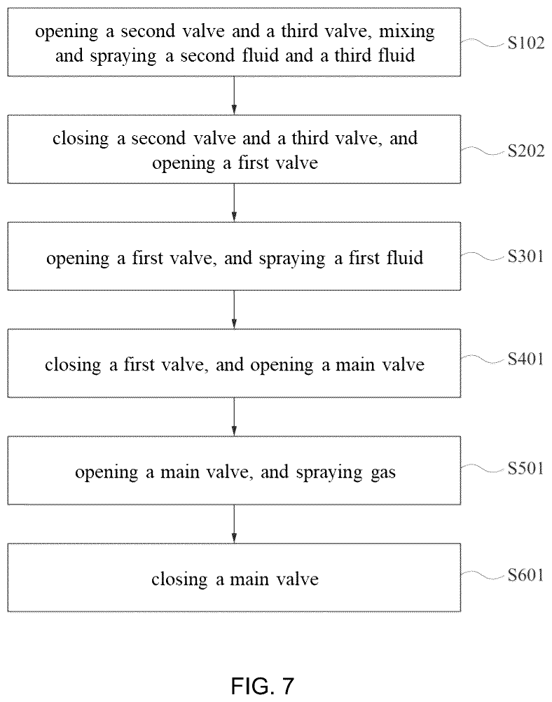

Refer to FIG. 7, which is a schematic flowchart of an operating method of a spraying device for a semiconductor substrate according to another embodiment of the present invention. Specifically, in this embodiment, the operating method of the spraying device 1 can include the following steps:
Step S102: opening the second valve V2 and the third valve V3, mixing and spraying the second fluid F2 and the third fluid F3;
Step S202: closing the second valve V2 and the third valve V3, and then controlling the first valve V1 to open; and
Step S301 to step S601 in subsequent.

The steps of the aforementioned operating method can be performed through the spraying system SYS. Specifically, multiple fluids (i.e., chemical solutions) can be mixed in the main channel 100 in advance, then sprayed, and then deionized water and nitrogen gas are then sprayed in sequence, so as to remove residual chemical solution in the main channel 100 and on the at least one semiconductor substrate 2. Other details about the spraying system SYS and the spraying device 1 have been described in the previous embodiments, and will not be reiterated herein.

Through the aforementioned embodiments, the spraying system SYS and the operating method of the spraying device 1 of the present invention allows the spraying device 1 to have a single main channel 100 and a single main channel outlet 100O, so that the gas G and the fluids F1, F2, F3 F4 can spray on the at least one semiconductor substrate 2 from the main channel outlet 100O uniformly without using different nozzles when spraying different gases or fluids, and can also reduce the time of unnecessary droplets of the chemical solution on the surface of the at least one semiconductor substrate 2, which can further enhance the overall yield of the semiconductor manufacturing process and reduce the risk of over-etching.

It is worth mentioning that the plurality of flow controllers 4 in the embodiment of the present invention control the flow rate of the gas G and the fluids F1, F2, F3, F4 through the opening time of each of the valves VM, V1, V2, V3, V4. The plurality of flow controllers 4 can also be replaced by flow meters in other embodiments, or by timers on the premise that the fluid flow rate is known. In this way, the overall cost of the spraying system SYS of the present invention can be further reduced.

The present invention chooses to determine whether the operation is completed by detecting whether the time reaches a preset value, which helps to accelerate the overall process, and only requires regular calibration of the flow controller, without wasting time to clearly determine the flow rate of gas or fluid flowing through the channel.

Therefore, the spraying device 1 for a semiconductor substrate and the spraying system SYS and operating method thereof provided by the present invention can reduce the amount of fluid that remains in the main channel 100 or the at least one branch channel P and prevent the chemical solution from dripping on the surface of the at least one semiconductor substrate 2 when the valve opening time has reached the required time preset value in the semiconductor manufacturing process, thereby preventing the chemical solution from forming crystals and enhancing the yield or productivity of the overall process (for example, enhancing the cleaning efficiency after wafer etching).), while reducing the number of replacements of expensive consumables and reducing process costs. In addition, since each of the valves VM, V1, V2, V3, V4 is provided in front of each of the at least one branch channel P, the fluid can be effectively prevented from dripping and flowing out of the main channel outlet 100O after each of the valves VM, V1, V2, V3, V4 is closed. Each of the at least one branch channel P, whether for fluids having a single component or fluids that are mixed with other fluids, flows out from the same outlet, i.e., the main channel outlet 100O. This can further prevent the problem of different nozzles or different channels from being difficult to be accurately positioned at the same position during operation, which causes the problem of yield reduction, and thus the points where the fluid is sprayed on the at least one semiconductor substrate 2 are consistent. In addition, by spraying the gas G after spraying the deionized water, the remaining moisture in the main channel 100 and at the main channel outlet 100O can also be quickly removed, thereby preventing a formation of moisture that causes the spraying device 1 to wear and corrode.

The above is only illustrative and not restrictive. Any equivalent modifications or changes that do not depart from the spirit and scope of the present invention shall be included in the appended patent scope.

Although the present disclosure has been disclosed in a number of preferred embodiments, it is not intended to limit the present disclosure, but only to enable those with ordinary knowledge to clearly understand the implementation content of the present disclosure. For a person of ordinary skill in the art, various changes and modifications can be made without departing from the spirit and scope of the present disclosure that is intended to be limited only by the appended claims.

What is claimed is:

1. A spraying device for spraying at least one semiconductor substrate, the spraying device comprising:
a main channel comprising a main channel inlet and a main channel outlet for gas to flow from the main channel inlet to the main channel outlet; and
at least one branch channel is communicated with the main channel, and each of the at least one branch channel has a branch channel inlet provided for fluid to flow from the branch channel inlet to the main channel outlet.

2. The spraying device according to claim 1, wherein the at least one branch channel further comprises:
a first branch channel, having a first branch channel inlet; and
a second branch channel, having a second branch channel inlet;
wherein, the first branch channel is more adjacent to the main channel inlet of the main channel than the second branch channel, so that a first fluid flows into the first branch channel from the first branch channel inlet, then enters the main channel, and then after passing through the second branch channel, the first fluid flows to the main channel outlet.

3. The spraying device according to claim 2, wherein the at least one branch channel further comprises:
a third branch channel, having a third branch channel inlet;
wherein, the third branch channel is further away from the main channel inlet of the main channel than the first branch channel and the second branch channel, so that the first fluid flows into the first branch channel from the first branch channel inlet, then enters the main channel, and then after passing through the second branch channel and the third branch channel in sequence, the first fluid flows to the main channel outlet.

4. The spraying device according to claim 3, wherein the second branch channel inlet is provided for a second fluid to flow from the second branch channel into the main channel, the third branch channel inlet is provided for a third fluid to flows from the third branch channel into the main channel, and the second fluid and the third fluid enter the main channel to be mixed and then flow to the main channel outlet.

5. The spraying device according to claim 1, wherein the at least one branch channel further comprises:
a first branch channel, having a first branch channel inlet; and
a second branch channel, having a second branch channel inlet;
wherein, a distance between a position where the first branch channel is communicated with the main channel and the main channel inlet of the main channel, and a position where the second branch channel is communicated with the main channel and the main channel inlet of the main channel in a vertical direction are the same.

6. The spraying device according to claim 1, wherein the main channel inlet and each of the branch channel inlet respectively have a valve to control opening or closing of the main channel and each of the at least one branch channel.

7. A spraying system, comprising:
at least one semiconductor substrate;
the spraying device according to claim 1 disposed above the at least one semiconductor substrate, wherein the main channel inlet and the branch channel inlet of the spraying device each have a valve for controlling opening or closing of the main channel and the at least one branch channel;
a plurality of flow controllers, respectively communicated with the valve of the main channel and the valve of each of the at least one branch channel, configured to monitor a flow rate of the gas or the fluid; and
a control module, signally connected to the spraying device and the plurality of flow controllers, configured to adjust flow of the gas or the fluid, and the opening or closing of the main channel and each of the at least one branch channel.

8. The spraying system according to claim 7, wherein the at least one branch channel further comprises a first branch channel and a second branch channel, and the main channel, the first branch channel, and the second branch channel respectively have a main valve, a first valve, and a second valve;
wherein, the first branch channel has a first branch channel inlet provided for a first fluid to flow from the first branch channel inlet to the main channel outlet, and the second branch channel has a second branch channel inlet provided for a second fluid to flow from the second branch channel inlet to the main channel outlet;
wherein, the first branch channel is more adjacent to the main channel inlet of the main channel than the second branch channel, so that the first fluid flows into the first branch channel from the first branch channel inlet, then enters the main channel, and then after passing through the second branch channel, the first fluid flows to the main channel outlet;
wherein, the main valve, the first valve, and the second valve are respectively provided to control opening or closing of the main channel, the first branch channel, and the second branch channel, and are respectively communicated with one of the plurality of flow controllers.

9. The spraying system according to claim 8, wherein the at least one branch channel further comprises:
a third branch channel having a third branch channel inlet provided for a third fluid to flow from the third branch channel inlet to the main channel outlet;
wherein, the first branch channel is more adjacent to the main channel inlet of the main channel than the second branch channel and the third branch channel, and the second branch channel is more adjacent to the main channel inlet than the third branch channel, so that the first fluid flows into the first branch channel from the first branch channel inlet, then enters the main channel, then after passing through the second branch channel and the third branch channel in sequence, the first fluid flows to the main channel outlet, and so that the second fluid flows into the second branch channel from the second branch channel inlet, then enters the main channel, and after passing through the third branch channel, the second fluid flows to the main channel outlet.

10. An operating method of the spraying system according to claim 8 for a semiconductor substrate, wherein the operating method comprises:
opening the second valve, and spraying the second fluid on the at least one semiconductor substrate.

11. The operating method according to claim 10 further comprises:
when detecting that an opening time of the second valve has reached a preset time value, closing the second valve, and opening the first valve.

12. The operating method according to claim 10 further comprises:
opening the first valve, and spraying the first fluid on the at least one semiconductor substrate.

13. The operating method according to claim 12 further comprises:
when detecting that an opening time of the first valve has reached a preset time value, closing the first valve, and opening the main valve.

14. The operating method according to claim 10 further comprises:
opening the main valve, and spraying the gas on the at least one semiconductor substrate.

15. The operating method according to claim 14 further comprises:
when detecting that an opening time of the main valve has reached a preset time value, closing the main valve.

16. An operating method of the spraying system for a semiconductor substrate according to claim 9, wherein the operating method comprises:
opening the second valve and the third valve, mixing the second fluid and the third fluid in the main channel, and spraying the second fluid and the third fluid on the at least one semiconductor substrate.

17. The operating method according to claim 16, wherein,
when detecting that an opening time of the second valve and an opening time of the third valve has reached a preset time value, closing the second valve and the third valve, and opening the first valve.
